(19) United States
(12) Patent Application Publication
(10) Pub. No.: US 2013/0082336 A1
(43) Pub. Date: Apr. 4, 2013

(54) SEMICONDUCTOR DEVICE AND METHOD FOR FABRICATING THE SAME

(71) Applicant: Tadahiro IMADA, Kawasaki (JP)

(72) Inventor: Tadahiro IMADA, Kawasaki (JP)

(73) Assignee: FUJITSU LIMITED, Kawasaki-shi (JP)

(21) Appl. No.: 13/552,883

(22) Filed: Jul. 19, 2012

(30) Foreign Application Priority Data
Sep. 29, 2011 (JP) 2011-214722

(51) Int. Cl. H01L 29/78; H01L 21/336

(52) U.S. Cl. 257/409; 438/197; 257/E29.255; 257/E21.409

(57) ABSTRACT

An AlGaN/GaN HEMT includes a compound semiconductor multilayer structure, an insertion metal layer in contact with a surface of the compound semiconductor multilayer structure, a gate insulating film formed on the insertion metal layer, and a gate electrode formed above the insertion metal layer with the gate insulating film between the gate electrode and the insertion metal layer.

### CROSS-REFERENCE TO RELATED APPLICATION

This application is based upon and claims the benefit of priority of the prior Japanese Patent Application No. 2011-214722, filed on Sep. 29, 2011, the entire contents of which are incorporated herein by reference.

### FIELD

The present embodiments relate to a semiconductor device and a method for fabricating the semiconductor device.

### BACKGROUND

Nitride semiconductors have high saturated electron velocities and wide bandgaps. Taking advantage of these and other characteristics, application of the nitride semiconductors to high-withstand-voltage and high-output semiconductor devices has been studied. For example, GaN, which is a nitride semiconductor, has a bandgap of 3.4 eV, which is higher than the bandgaps of Si (1.1 eV) and GaAs (1.4 eV), and has a higher breakdown field strength. For this reason, GaN holds great promise as a material of power-supply semiconductor devices that provide high-voltage operation and high output.

For nitride-semiconductor-based devices, many reports on nitride-semiconductor-based field-effect transistors, especially High Electron Mobility Transistors (HEMTs), have been made. For example, research on GaN-based HEMTs (GaN-HEMTs) has focused on AlGaN/GaN HEMTs that use GaN for an electron transit layer and AlGan for an electron donor layer. In the AlGaN/GaN HEMTs, strain in AlGaN is caused by the difference in grating constant between GaN and AlGaN. Piezoelectric polarization and AlGaN spontaneous polarization caused by the strain provide a high-concentration two-dimensional electron gas (2DEG), which makes AlGaN/GaN HEMTs desirable for use as high-efficiency switch elements and high-withstand-voltage power devices for electric vehicles.
Patent Document 1: Japanese Laid-Open Patent Publication No. 2007-220895

To use a nitride semiconductor device as a switching device, the gate voltage needs to be sufficiently driven positive while the device is operating (in the on-state) so that the gate voltage threshold value is positive and the influence of noise is avoided. To achieve this, a Metal-Insulator-Semiconductor (MIS) structure is preferable to the Schottky structure, which has been conventionally used in RF applications.

However, when the MIS structure is used in a nitride semiconductor device, unwanted charge builds up at the interface between the electrode and the insulating film, which causes an increase in on-state resistance, threshold variations, and degradation of the reliability of the device. The problem is a serious concern in putting nitride semiconductor device with the MIS structure into practical use.

### SUMMARY

One mode of a semiconductor device includes a semiconductor layer, a first conductive layer in contact with a surface of the semiconductor layer, an insulating film formed on the first conductive layer, and a second conductive layer formed above the first conductive layer with the insulating film between the first conductive layer and the second conductive layer.

One mode of a method for fabricating a semiconductor device includes forming a semiconductor layer; forming a first conductive layer in contact with a surface of the semiconductor layer; forming an insulating film on the first conductive layer; and forming a second conductive layer in a region on the insulating film, the region being located above and vertically aligned with the first conducive layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view illustrating a method for fabricating an AlGaN/GaN HEMT according to a first embodiment step by step;

FIG. 2 is a schematic cross-sectional view continued from FIG. 1 illustrating step by step the method for fabricating the AlGaN/GaN HEMT according to the first embodiment;

FIG. 3 is a schematic cross-sectional view continued from FIG. 2 illustrating step by step the method for fabricating the AlGaN/GaN HEMT according to the first embodiment;

FIG. 4 is a schematic plan view illustrating a configuration of the AlGaN/GaN HEMT according to the first embodiment;

FIG. 5 is a characteristics diagram illustrating the results of an investigation on the relationship between drain-source voltage Vds and gate current Ig in the first embodiment;

FIG. 6 is a schematic plan view illustrating a HEMT chip using the AlGan/GaN HEMT according to the first embodiment;

FIG. 7 is a schematic plan view illustrating a discrete package using the AlGaN/GaN HEMT according to the first embodiment;

FIG. 8 is a schematic cross-sectional view illustrating principal steps for fabricating an AlGaN/GaN HEMT according to a second embodiment;

FIG. 9 is a schematic cross-sectional view continued from FIG. 8 illustrating principal steps for fabricating the AlGaN/GaN HEMT according to the second embodiment;

FIG. 10 is a characteristics diagram illustrating the results of an investigation on the relationship between drain-source voltage Vds and drain current Id in the second embodiment;

FIG. 11 is a schematic cross-sectional view illustrating principal steps for fabricating an MIS type AlGaN/GaN HEMT according to a variation of the second embodiment;

FIG. 12 is a characteristics diagram illustrating the results of an investigation on the relationship between drain-source voltage Vds and drain current Id in a variation of the second embodiment;

FIG. 13 is a connection diagram of a PFC circuit according to a third embodiment;

FIG. 14 is a connection diagram illustrating a general configuration of a power supply device according to a fourth embodiment; and

FIG. 15 is a connection diagram illustrating a general configuration of a high-frequency amplifier according to a fifth embodiment.

### DESCRIPTION OF EMBODIMENTS

Embodiments will be described with reference to drawings. Configurations of compound semiconductor devices will be described in conjunction with methods for fabricating the devices in the embodiments below.

It is noted that for convenience of illustration, the sizes and thicknesses of some of the components in the drawings are not depicted to scale.

### First Embodiment

In a first embodiment, a Metal-Insulator-Semiconductor (MIS) type AlGaN/GaN HEMT will be disclosed as a compound semiconductor device.

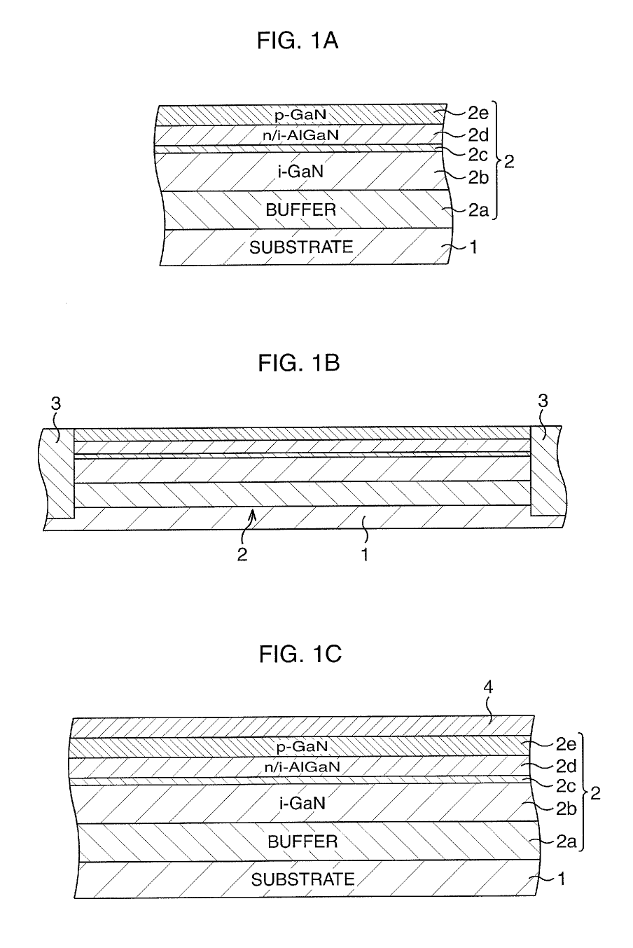

FIGS. 1 to 3 are schematic cross-sectional views illustrating step by step a method for fabricating an MIS type AlGaN/GaN HEMT according to the first embodiment.

As illustrated in FIG. 1A, first a compound semiconductor multilayer structure 2 is formed on a growth substrate, for example a Si substrate 1. The growth substrate may be of other material such as a sapphire substrate, a GaAs substrate, a SiC substrate, or a GaN substrate. The substrate may be a semi-insulating substrate or a conductive substrate.

The compound semiconductor multilayer structure 2 includes a buffer layer 2a, an electron transit layer 2b, an intermediate layer (spacer layer) 2c, an electron donor layer 2d, and p-type cap layer 2e. Here, the electron transit layer 2b has a negative polarity so that two-dimensional electron gas is produced at the interface with the intermediate layer 2c as will be described later. On the other hand, the p-type cap layer 2e has a positive polarity because the p-type cap layer 2e is opposite in conductivity to the n-type.

Specifically, the following compound semiconductors are grown on the Si substrate 1 by Metal Organic Vapor Phase Epitaxy (MOVPE), for example. Other method such as Molecular Beam Epitaxy (MBE) may be used instead of MOVPE.

Compound semiconductors that will serve as the buffer layer 2a, electron transit layer 2b, the intermediate layer 2c, the electron donor layer 2d, and the p-type cap layer 2e are grown on the Si substrate 1 in that order. The buffer layer 2a is formed by growing AlN on the Si substrate 1 to a thickness of approximately 0.1 μm. The electron transit layer 2b is formed by growing (intentionally undoped)-GaN to a thickness in the range of approximately 1 μm to approximately 3 μm. The intermediate layer 2c is formed by growing i-AlGaN to a thickness of approximately 5 nm. The donor layer 2d is formed by growing n-AlGaN to a thickness of approximately 30 nm. The intermediately layer 2c may be omitted. The electron donor layer may be formed of i-AlGaN.

The p-type cap layer 2e is formed by growing p-GaN to a thickness in the range of approximately 10 nm to approximately 1000 nm, for example. If the p-type cap layer 2e is thinner than 10 nm, a desired normally-off operation cannot be achieved; if the p-type cap layer 2e is thicker than 1000 nm, the distance from a gate electrode to the AlGaN/GaN hetero interface, which acts as a channel, will be long so that response speed will decrease and electric fields from the gate electrode in the channel will be insufficient, thereby causing defects such as poor pinch-off. Therefore, the p-type cap layer 2e is formed to a thickness in the range of approximately 10 nm to approximately 1000 nm to ensure high response speed and prevent degradation of the device characteristics, such as poor pinch-off while achieving a proper normally-off operation. In this embodiment, p-GaN of the p-type cap layer 2e is formed to a thickness of approximately 200 nm.

To grow GaN, mixed gas of trimethyl gallium (TMGa) gas, which is the Ga source, and ammonium (NH₃) gas is used as material gas. To grow AlGaN, mixture gas of TMAl gas, TMGa gas and NH₃ gas is used as the material gas. Supplying and discontinuing supplying the TMAl and TMGa gases and the flow rates of the TMAl and TMGa gases are set as appropriate according to the compound semiconductor layer to grow. The flow rate of the NH₃ gas, which is a material common to the layers, is set to a value in the range of approximately 100 sccm to approximately 10 slm. The growth pressure is set to a value in the range of approximately 50 Torr to 300 Torr and the growth temperature is set to a value in the range of approximately 1000° C. to 1200° C.

When AlGaN is grown as the n-type, that is, when the electron donor layer 2d (n-AlGaN) is formed, an n-type impurity is added to the material gas of AlGaN. Here, for example silane (SiH₄) gas containing Si for example is added at a given flow rate to the material gas to dope AlGaN with Si. The doping concentration of Si is set to a value in the range of approximately 1×10¹⁸/cm³ to approximately 1×10²⁰/cm³, for example approximately 2×10¹⁸/cm³.

When GaN is grown as the p-type, that is, when the p-type cap layer 2e (p-GaN) is formed, a p-type impurity, for example an impurity selected between Mg and C, is added to the material gas of GaN. In this embodiment, Mg is used as the p-type impurity. Mg is added at a given flow rate to the material gas to dope GaN with Mg. The doping concentration of Mg is in the range of approximately 1×10¹⁶/cm³ to approximately 1×10²¹/cm³, for example. If the doping concentration is less than approximately 1×10¹⁶/cm³, GaN is not sufficiently doped to p-type and the p-type cap layer 2e will be normally on; if the doping concentration is greater than approximately 1×10²¹/cm³, crystallinity will degrade and sufficiently good characteristics cannot be provided. By choosing a Mg doping concentration in the range of approximately 1×10¹⁶/cm³ to approximately 1×10²¹/cm³, a p-type semiconductor that provides sufficiently good characteristic can be produced. In this embodiment, the Mg doping concentration in the p-type cap layer 2e is approximately 1×10¹⁹/cm³.

In the compound semiconductor multilayer structure 2 thus formed, piezoelectric polarization is caused at the interface of the electron transit layer 2b having the negative polarity with the electron donor layer 2d (to be exact, the interface with the intermediate layer 2c, which will be hereinafter referred to as the GaN/AlGaN interface) by a distortion due to the difference in lattice constant between GaN and AlGaN. The effect of the piezoelectric polarization in combination with the effect of spontaneous polarization in the electron transit layer 2b and the electron donor layer 2d produces two-dimensional electron gas (2DEG) with a high electron concentration at the GaN/AlGaN interface.

After the compound semiconductor multilayer structure 2 has been formed, the p-type cap layer 2e is annealed at approximately 700° C. for approximately 30 minutes.

An element isolating structure 3 is formed as illustrated in FIG. 1B. The element isolating structure 3 is omitted from FIG. 1C and the subsequent drawings.

Specifically, argon (Ar), for example, is injected into the element isolating region of the compound semiconductor multilayer structure 2. As a result, the element isolating structure 3 is formed in the compound semiconductor multilayer structure 2 and a surface portion of the Si substrate 1. An active region is defined on the compound semiconductor multilayer structure 2 by the element isolating structure 3.

It is noted that element isolation may be made by other known method such as Shallow Trench Isolation (STI), for example, instead of the injection method described above. Here, chlorine-based etching gas, for example, is used for dry etching of the compound semiconductor multilayer structure 2.

Then, an insertion metal layer 4 is formed on the compound semiconductor multilayer structure 2 as illustrated in FIG. 1C.

Specifically, a conductive material is deposited on the surface of the compound semiconductor multilayer structure 2 (the surface of the p-type cap layer 2e) by a method such as vapor deposition or sputtering. The conductive material may be any metal that forms an ohmic contact with p-GaN of the p-type cap layer 2e and is preferably at least one metal selected from the group consisting of Ti, Ni, and Pd, for example. In this example, Ni is deposited as the conductive material to a thickness of approximately 30 nm, for example.

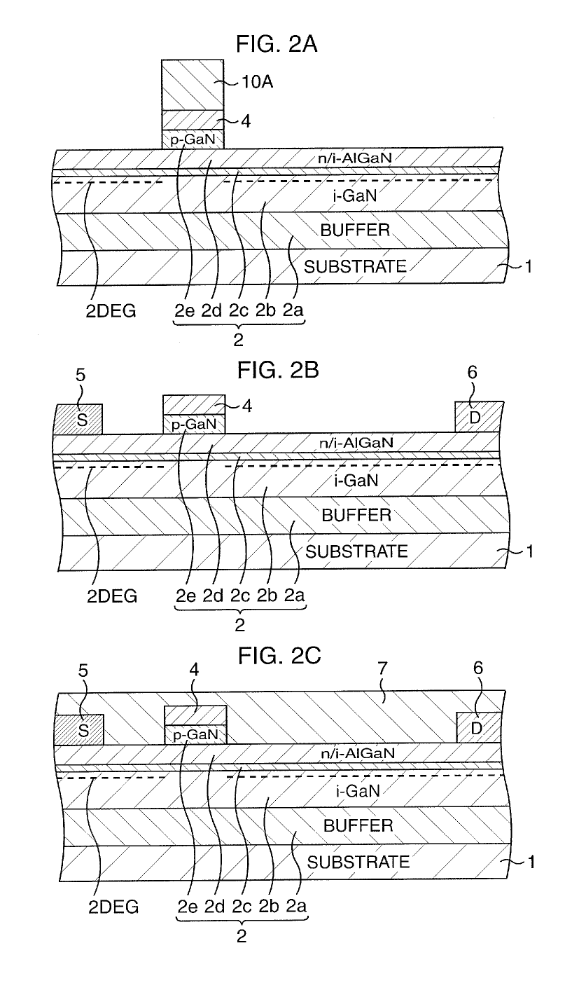

Then, the insertion metal layer 4 and the p-type cap layer 2e are shaped into the geometry of an electrode as illustrated in FIG. 2A.

Specifically, a resist is applied to the insertion metal layer 4 and processed by lithography. As a result, a resist mask 10A that covers a predetermined region in the insertion metal layer 4, here, a region corresponding to a location where a gate electrode is to be formed, is formed.

Then, the resist mask 10A is used to etch the insertion metal layer 4 and the p-type cap layer 2e by dry etching. As a result, the p-type cap layer 2e and the insertion metal layer 4 are left only the region where the gate electrode is to be formed on the electron donor layer 2d. The p-type cap layer 2e and the insertion metal layer 4 is left in a predetermined region closer to a location where a source electrode is to be formed than a location where a drain electrode is to be formed.

The resist mask 10A is then removed by ashing or a wet process with a predetermined chemical.

In the compound semiconductor multilayer structure 2, the p-type cap layer 2e is localized only in the region describe above and p-GaN does not exist in the other regions. Accordingly, 2DEG is produced at the GaN/AlGaN interface, except the region under the p-type cap layer 2e. In the region under the p-type cap layer 2e, practically no 2DEG is produced because of the presence of p-GaN.

Then a source electrode 5 and a drain electrode 6 are formed as illustrated in FIG. 2B.

Specifically, a resist mask for forming the source electrode and the drain electrode is formed first. Here, for example an overhanging double layer resist, which is suitable for vapor deposition and lift-off, is used. The resist is applied to the compound semiconductor multilayer structure 2 to form openings that expose a region where the source electrode is to be formed and a region where the drain electrode is to be formed on the surface of the electron donor layer 2d. This completes a resist mask having the openings.

An electrode material, for example Ta/Al is deposited on the resist mask, including the regions inside the openings, by vapor deposition, for example. Ta is deposited to a thickness of approximately 20 nm; Al is deposited to a thickness of approximately 200 nm. Then the resist mask and Ta/Al deposited on the resist mask are removed by lift-off. Thereafter, the Si substrate 1 is heat-treated at a temperature in the range of 400° C. to 1000° C., for example approximately 600° C., in a nitrogen atmosphere, for example, to bring the remaining Ta/Al into ohmic contact with the electron donor layer 2d. The heat treatment may be omitted if ohmic contact between Ta/Al and the electron donor layer 2d can be made without the heat treatment. In this way, the source electrode 5 and the drain electrode 6 are formed.

Then, a gate insulating film 7 is formed as illustrated in FIG. 2C.

Specifically, an insulating material, for example Al₂O₃ is deposited on the compound semiconductor multilayer structure 2 to cover the insertion metal layer 4 and the p-type cap layer 2e. To deposit Al₂O₃, TMA gas and O₃ are alternately supplied by Atomic Layer Deposition (ALD), for example. In this embodiment, Al₂O₃ is deposited so that the thickness of Al₂O₃ on the insertion metal layer 4 is in the range of approximately 2 nm to approximately 200 nm, for example approximately 10 nm in this embodiment. In this way, the gate insulating film 7 is formed.

Alternatively, Al₂O₃ may be deposited by plasma CVD or sputtering instead of ALD. Furthermore, instead of Al₂O₃, a nitride or oxynitride of alumina may be deposited. Alternatively, an oxide, nitride, or oxynitride of Si, Hf, Zr, Ti, Ta, or W, or any of these compounds may be selected as appropriate to deposit in multiple layers to form the gate insulating film.

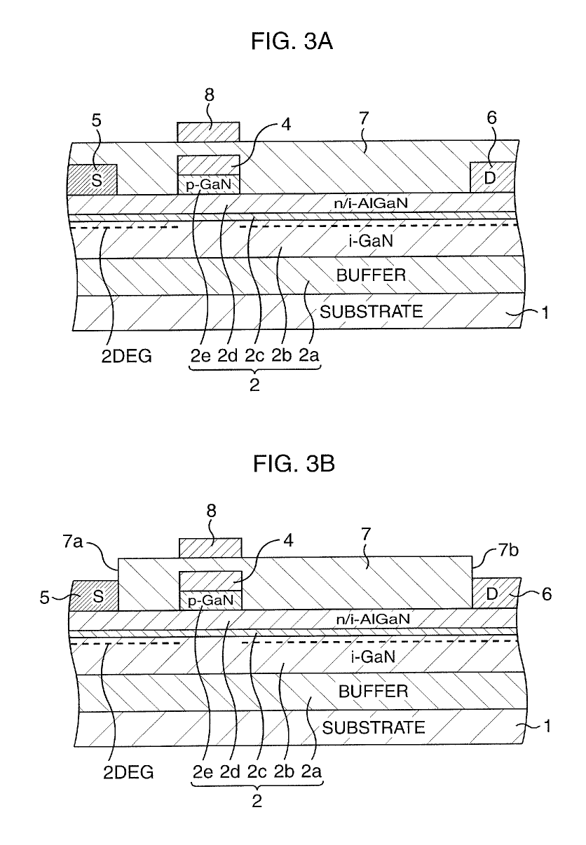

Then, a gate electrode 8 is formed as illustrated in FIG. 3A.

Specifically, a resist mask for forming the gate electrode is formed on the gate insulating film 7 first. A resist is applied to the gate insulating film 7 and an opening is formed to expose a region in the surface of the gate insulating film 7 that is located above and vertically aligned with the insertion metal layer 4. In this way, a resist mask having the opening is formed.

An electrode material, for example Ni/Au is deposited on the resist mask, including the region inside the opening, by vapor deposition, for example. Ni is deposited to a thickness of approximately 30 nm; Au is deposited to a thickness of approximately 400 nm. Then the resist mask and Ni/Au deposited on the resist mask are removed by lift-off. In this way, the gate electrode 8 is formed in the region on the surface of the gate insulating film 7 located above and vertically aligned with the insertion metal layer 4.

Then openings 7a and 7b are formed in the gate insulating film 7 on the source electrode 5 and the drain electrode 6 as illustrated in FIG. 3B.

Specifically, lithography and dry etching are performed to remove the portion of the gate insulating film 7 on the source electrode 5 and the portion of the gate insulating film 7 on the drain electrode 6. As a result, openings 7a and 7b that expose the surface of the source electrode 5 and the surface of the drain electrode 6 are formed in the gate insulating film 7.

Thereafter, steps such as the steps of electrically interconnecting the source electrode 5, the drain electrode 6, and the gate electrode 8 and forming pads for the source electrode 5, the drain electrode 6, and the gate electrode 8 are performed to complete an MIS type AlGaN/GaN HEMT according to this embodiment.

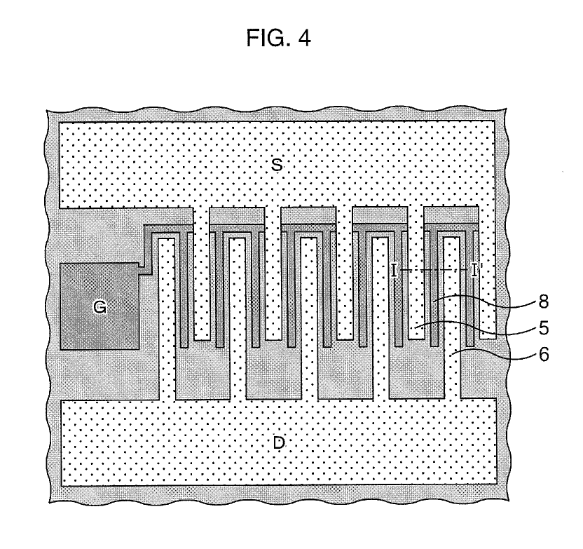

FIG. 4 is a plan view of the AlGaN/GaN HEMT according to this embodiment.

The cross section taken along dashed line I-I′ in FIG. 4 is the cross-sectional view of FIG. 3B. In this way, the source electrode 5 and the drain electrode 6 are formed parallel to each other like comb teeth and the comb-tooth-like gate electrode 8 is disposed between and parallel with the source electrode 5 and the drain electrode 6.

The AlGaN/GaN HEMT according to this embodiment has an MIS type structure in which the gate insulating film is disposed between the compound semiconductor and the gate electrode. Here, the gate insulating film 7 is disposed between the compound semiconductor multilayer structure 2 and the gate electrode 8 with the insertion metal layer 4 that vertically aligns with the gate electrode 8 between the gate insulating film 7 and the compound semiconductor multilayer structure 2. In a configuration in which the insertion metal layer 4 is not provided, unwanted charge can build up in the gate insulating film or at the interface between the compound semiconductor multilayer structure and the gate insulating film. In the configuration of this embodiment, in contrast, the insertion metal layer 4 prevents the buildup of unwanted charge, thereby minimizing a rise of on-state resistance and threshold variations.

Furthermore, in the AlGaN/GaN HEMT according to this embodiment, the p-type cap layer 2e of the compound semiconductor multilayer structure 2 is provided only in a region located under and vertically aligned with the gate electrode 8 and, during non-operation, there is practically no 2DEG, except under the p-type cap layer 2e. This configuration provides a desired normally-off operation. That is, when the gate voltage is off, there is not 2DEG in the channel and therefore the normally-off state is provided; when the gate voltage is on, desired 2DEG is produced in the channel to drive.

While a p-type compound semiconductor is used for the cap layer of the compound semiconductor multilayer structure in this embodiment, an n-type compound semiconductor (n-GaN) may be used instead. In that case, the cap layer does not need to be shaped into the geometry of electrodes together with the insertion metal layer. The insertion metal layer may be made of any conductive material that makes ohmic contact with n-GaN of n-type cap layer. The conductive material is preferably at least one selected between Ta and Al, for example.

Here, an experiment conducted to investigate characteristics of the AlGaN/GaN HEMT according to this embodiment will be described. For comparison with this embodiment, an AlGaN/GaN HEMT that does not include an insertion metal layer will be taken as an example.

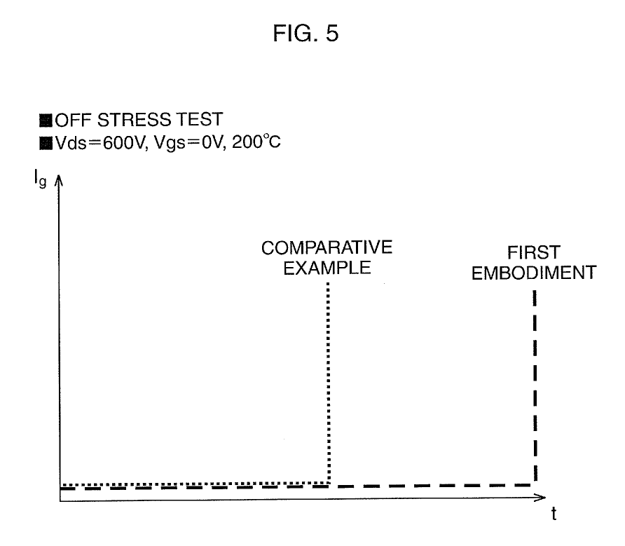

In this experiment, a gate voltage Vg was continuously applied to determine the time that elapsed before breakdown (off stress test). Here, Vds of 600 V was applied at a temperature of 200° C. and a gate-source voltage Vgs was set to 0 V. FIG. 5 gives the results of the experiment. The results demonstrate that the time required for breakdown to occur increases and the reliability of the device is improved in this embodiment as compared with the comparative example.

As has been described above, this embodiment implements a highly reliable, high-withstand-voltage AlGaN/GaN HEMT that has an MIS structure in which an insulating film is provided between a compound semiconductor multilayer structure 2 and a gate electrode 8 and yet minimizes a rise in on-state resistance and threshold variations.

The AlGaN/GaN HEMT according to this embodiment is applicable to the so-called discrete package.

An AlGaN/GaN HEMT chip according to this embodiment is mounted on the discrete package. The discrete package of the AlGaN/GaN HEMT chip according to this embodiment (hereinafter referred to as the HEMT chip) will be described below.

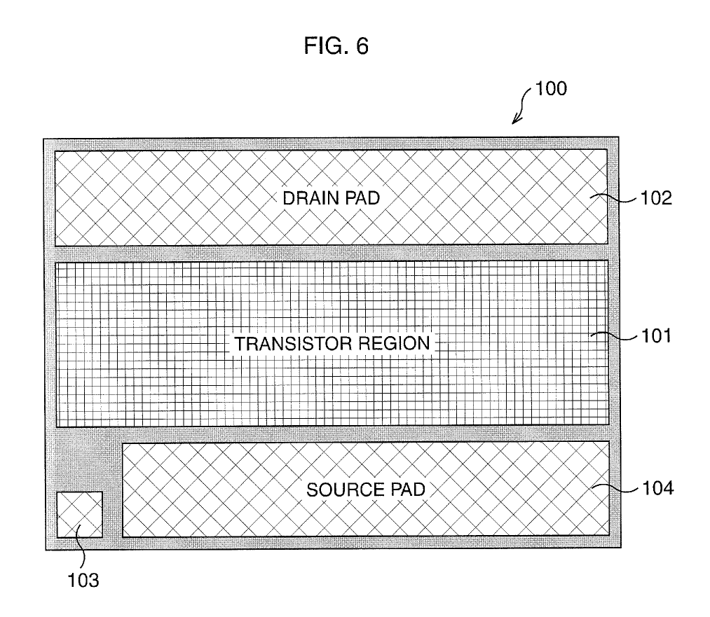

FIG. 6 schematically illustrates a configuration of the HEMT chip (corresponding to FIG. 4).

A transistor region 101 of the AlGaN/GaN HEMT described above, a drain pad 102 to which drain electrodes are connected, a gate pad 103 to which gate electrodes are connected, and a source pad 104 to which source electrodes are connected are provided on a surface of the HEMT chip 100.

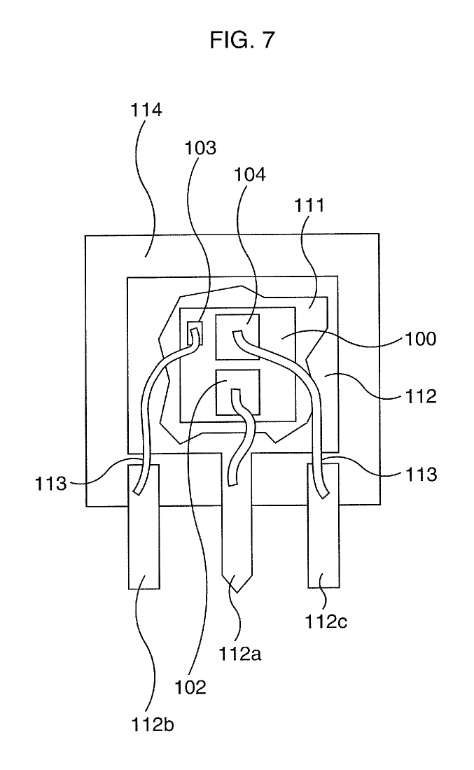

FIG. 7 is a schematic plan view of the discrete package.

To fabricate the discrete package, first the HEMT chip 100 is fixed to a lead frame 112 with a die attach paste 111 such as solder. A drain lead 112a is formed monolithically with the lead frame 112 and a gate lead 112b and a source lead 112c are disposed separately and spaced apart from the lead frame 112.

Then, bonding with Al wires 113 is performed to electrically connect the drain pad 102 with the drain lead 112a, the gate pad 103 with the gate lead 112b, and the source pad 104 with the source lead 112c.

Thereafter, the HEMT chip 100 is encapsulated with molding resin 114 by transfer molding and the lead frame 112 is cut off. Thus, a discrete package is completed.

### Second Embodiment

In a second embodiment, an MIS type AlGaN/GaN HEMT will be disclosed as a compound semiconductor device.

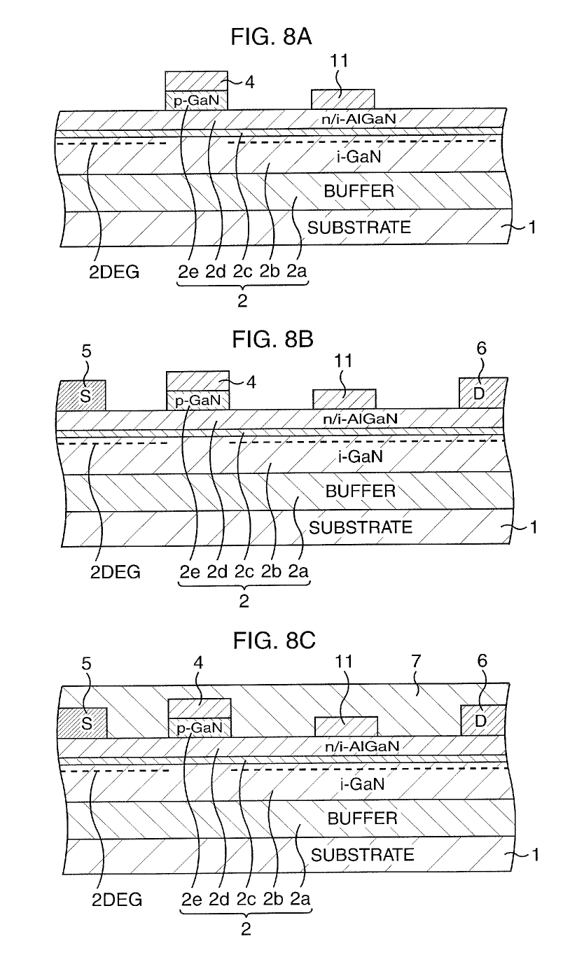

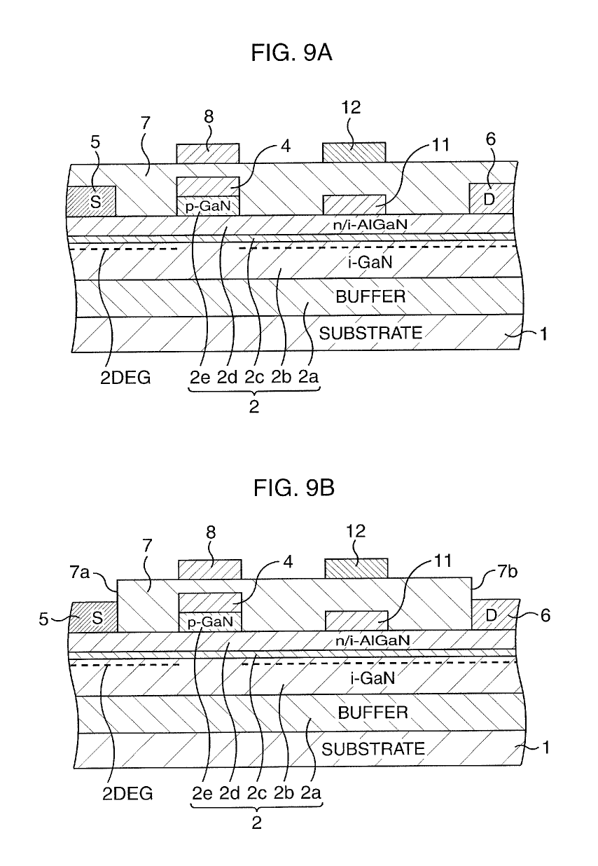

FIGS. 8 and 9 are schematic cross-sectional views illustrating principal steps of a method for fabricating an MIS type AlGaN/GaN HEMT according to the second embodiment. The same components as those of the first embodiments are given the same reference numerals and detailed description of those components will be omitted.

As in the first embodiment, first the steps in FIGS. 1A to 2A are performed in sequence.

Then, an insertion metal layer 11 is formed on the compound semiconductor multilayer structure 2 as illustrated in FIG. 8A.

Specifically, first a resist mask for forming the insertion metal layer is formed. A resist is applied to the compound semiconductor multilayer structure 2 and an opening is formed that exposes a region in the surface of the electron donor layer 2d where the insertion metal layer is to be formed. In this way, a resist mask having the openings is formed.

A conductive material is deposited on the resist mask, including the region inside the opening, by a method such as vapor deposition or sputtering, for example. The conductive material may be any metal that makes an ohmic contact with n-AlGaN of the electron donor layer 2d and is preferably at least one selected between Ta and Al, for example. In this embodiment, Ta is deposited as the conductive material to a thickness of approximately 20 nm, for example.

The resist mask and Ta deposited on the resist mask are removed by lift-off. As a result, an insertion metal layer 11 is formed. The insertion metal layer 11 is formed in a location between the insertion metal layer 4 and the location where a drain electrode is to be formed, closer to the location where the drain electrode is to be formed than the location where a source electrode is to be formed.

Then, a source electrode 5 and a drain electrode 6 are formed as illustrated in FIG. 8B.

Specifically, first a resist mask for forming the source electrode and the drain electrode is formed. Here, a resist suitable for vapor deposition and lift-off, for example an overhanging double layer resist, is used. The resist is applied to the compound semiconductor multilayer structure 2 and openings are formed that expose a region on the surface of the electron donor layer 2d where the source electrode is to be formed and a region where the drain electrode is to be formed. In this way, a resist mask including the openings is formed.

An electrode material, for example Ta/Al is deposited on the resist mask, including the regions inside the openings by vapor deposition, for example. Ta is deposited to a thickness of approximately 20 nm; Al is deposited to a thickness of approximately 200 nm. The resist mask and the Ta/Al deposited on the resist mask are removed by lift-off. Thereafter, the Si substrate 1 is heat-treated in a nitrogen atmosphere, for example, at a temperature in the range of 400° C. to 1000° C., for example approximately 600° C. to bring the remaining Ta/Al into ohmic contact with the electron donor layer 2d. The heat treatment may be omitted if ohmic contact between Ta/Al and the electron donor layer 2d can be made without the heat treatment. In this way, the source electrode 5 and the drain electrode 6 are formed.

Then a gate insulating film 7 is formed as illustrated in FIG. 8C.

Specifically, an insulating material, for example Al₂O₃ is deposited on the compound semiconductor multilayer structure 2 to cover the insertion metal layer 4 and the p-type cap layer 2e. To deposit Al₂O₃, TMA gas and O₃ are alternately supplied by ALD, for example. In this embodiment, Al₂O₃ is deposited so that the thickness of Al₂O₃ on the insertion metal layer 4 is in the range of approximately 2 nm to approximately 200 nm, for example approximately 10 nm in this embodiment. In this way, the gate insulating film 7 is formed.

Alternatively, Al₂O₃ may be deposited by plasma CVD or sputtering instead of ALD. Furthermore, instead of Al₂O₃, a nitride or oxynitride of alumina may be deposited. Alternatively, an oxide, nitride, or oxynitride of Si, Hf, Zr, Ti, Ta, or W, or any of these compounds may be selected as appropriate to deposit in multiple layers to form the gate insulating film.

Then, a gate electrode 8 and a field-plate electrode 12 are formed as illustrated in FIG. 9A.

Specifically, first a resist mask for forming the gate electrode and the field-plate electrode is formed on the insulating film 7. A resist is applied to the gate insulating film 7 and openings are formed to expose regions in the surface of the gate insulating film 7 that are located above and vertically aligned with the insertion metal layer 4, 11 by lithography. In this way, a resist mask having the openings is formed.

An electrode material, for example Au is deposited on the resist mask, including the regions inside the openings, by vapor deposition, for example. Au is deposited to a thickness of approximately 300 nm. Then the resist mask and Au deposited on the resist mask are removed by lift-off. In this way, the gate electrode 8 is formed in the region on the surface of the gate insulating film 7 located above and vertically aligned with the insertion metal layer and the field-plate electrode 12 is formed in the region located above and vertically aligned with the insertion metal layer 11.

In an AlGaN/GaN HEMT, a higher voltage is applied to a drain electrode than the voltages applied to source and gate electrodes in some cases. In this embodiment, an electric field produced by application of a high voltage can be reduced by the field-plate electrode 12 provided.

Then openings 7a and 7b are formed in the gate insulating film 7 on the source electrode 5 and the drain electrode 6 as illustrated in FIG. 9B.

Specifically, lithography and dry etching are performed to remove the portion of the gate insulating film 7 on the source electrode 5 and the portion of the gate insulating film 7 on the drain electrode 6. As a result, openings 7a and 7b that expose the surface of the source electrode 5 and the surface of the drain electrode 6 are formed in the gate insulating film 7.

Thereafter, steps such as the steps of electrically interconnecting the source electrode 5, the drain electrode 6, and the gate electrode 8 and forming pads for the source electrode 5, the drain electrode 6, and the gate electrode 8 are performed to complete an AlGaN/GaN MIS HEMT according to this embodiment.

The AlGaN/GaN HEMT according to this embodiment has an MIS type structure in which the gate insulating film is disposed between the compound semiconductor and the gate electrode. Here, the gate insulating film 7 is disposed between the compound semiconductor multilayer structure 2 and the gate electrode 8 with the insertion metal layer 4 that vertically aligns with the gate electrode 8 between the gate insulating film 7 and the chemical compound multilayer structure 2. In a configuration in which the insertion metal layer 4 is not provided, unwanted charge can build up in the gate insulating film or at the interface between the compound semiconductor multilayer structure and the gate insulating film. In the configuration of this embodiment, in contrast, the insertion metal layer 4 prevents the buildup of unwanted charge, thereby improving the reliability of the device.

The AlGaN/GaN HEMT according to this embodiment has an MIS type structure in which the gate insulating film is disposed between the compound semiconductor and the field-plate electrode. Here, an insulating film (the gate insulating film 7) is disposed between the compound semiconductor multilayer structure 2 and the field-plate electrode 12 with the insertion metal layer 11 that aligns with the field-plate electrode 12 between the gate insulating film 7 and the chemical compound multilayer structure 2. In a configuration in which the insertion metal layer 11 is not provided, unwanted charge can build up in the gate insulating film or at the interface between the compound semiconductor multilayer structure and the gate insulating film. In the configuration of this embodiment, in contrast, the insertion metal layer 11 prevents the buildup of unwanted charge. Accordingly, such unwanted charge is not produced and electric fields produced by application of a high voltage to the drain electrode are reduced by the field-plate electrode 12, thereby significantly improving the reliability of the device.

Furthermore, in the AlGaN/GaN HEMT according to this embodiment, the p-type cap layer 2e of the compound semiconductor multilayer structure 2 is provided only in a region located under and vertically aligned with the gate electrode 8 and, during non-operation, there is practically no 2DEG, except under the p-type cap layer 2e. This configuration provides a desired normally-off operation. That is, when the gate voltage is off, there is not 2DEG in the channel and therefore the normally-off state is provided; when the gate voltage is on, desired 2DEG is produced in the channel to drive.

Here, an experiment conducted to investigate characteristics of the AlGaN/GaN HEMT according to this embodiment will be described. For comparison with this embodiment, an AlGaN/GaN HEMT that does not include insertion metal layers will be taken as an example.

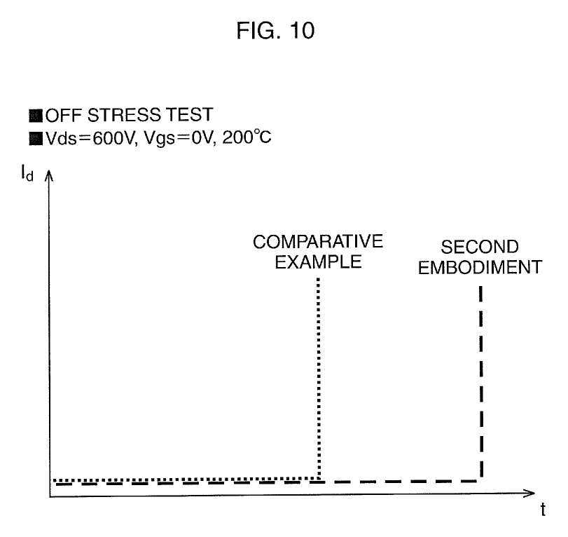

In this experiment, a voltage Vds was continuously applied across the source and drain to determine the time that elapsed before breakdown (off stress test). Here, a Vds of 600 V was applied at a temperature of 200° C. and the gate-source voltage Vgs was set to 0 V. FIG. 10 gives the results of the experiment. The results demonstrate that the time required for breakdown to occur increases and the reliability of the device is improved in this embodiment as compared with the comparative example.

As has been described above, this embodiment implements a highly reliable, high-withstand-voltage AlGaN/GaN HEMT that has an MIS structure in which an insulating film is provided between a compound semiconductor multilayer structure 2 and a gate electrode 8 and yet minimizes a rise in on-state resistance and threshold variations.

(Variation)

A variation of the second embodiment will be described below.

The exemplary variation disclosed here is an MIS type AlGaN/GaN HEMT similar to that of the second embodiment, with the only difference being the configuration of the field-plate electrode.

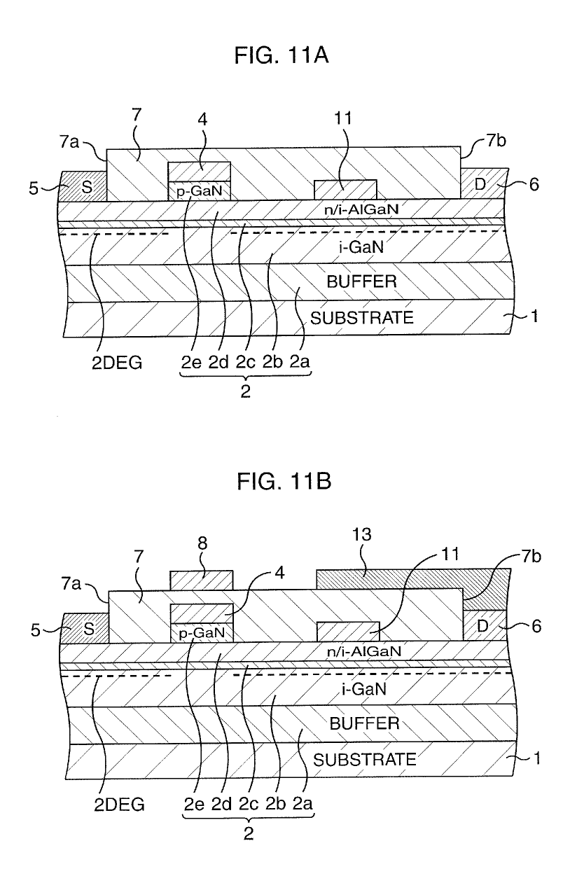

FIG. 11 is a schematic cross-sectional view illustrating principal steps of a method for fabricating an MIS type AlGaN/GaN HEMT according to the variation of the second embodiment. The same components as those of the second embodiments are given the same reference numerals and detailed description of those components will be omitted.

First, as in the second embodiment, the steps in FIGS. 1A to 2A of the first embodiment are performed and then the steps in FIGS. 8A to 8C of the second embodiment are performed in sequence.

Then openings 7a and 7b are formed in the gate insulating film 7 on the source electrode 5 and the drain electrode 6 as illustrated in FIG. 11A.

Specifically, lithography and dry etching are performed to remove the portion of the gate insulating film 7 on the source electrode 5 and the portion of the gate insulating film 7 on the drain electrode 6. As a result, openings 7a and 7b that expose the surface of the source electrode 5 and the surface of the drain electrode 6 are formed in the gate insulating film 7.

Then, a gate electrode 8 and a field-plate electrode 13 are formed as illustrated in FIG. 11B.

Specifically, first a resist mask for forming the gate electrode and the field-plate electrode is formed on the insulating film 7. A resist is applied to the gate insulating film 7 and lithography is performed to form an opening that exposes a region on the surface of the gate insulating film 7 that is located above and vertically aligns with the insertion metal layer 4 and an opening that exposes a region on the surface of the gate insulating film 7 that is located above and vertically aligns with the insertion metal layer 11 and the opening 7b adjacent to that region. In this way, a resist mask having the openings is formed.

An electrode material, for example Au is deposited on the resist mask, including the regions inside the openings, by vapor deposit, for example. Au is deposited to a thickness of approximately 300 nm, for example. Then the resist mask and Au deposited on the resist mask are removed by lift-off. In this way, a gate electrode 8 is formed in the region on the surface of the gate insulating film 7 that is located above and vertically aligned with the insertion metal layer 4. In addition, a field-plate electrode 13 is formed from the region on the surface of the gate insulating film 7 that is located above and vertically aligned with the insertion metal layer so that the material of the electrode fills the opening 7b to electrically connect to the drain electrode 6. The field-plate electrode 13 is electrically connected to the drain electrode 6 to serve as the so-called drain-field-plate electrode.

In an AlGaN/GaN HEMT, a higher voltage is applied to a drain electrode than the voltages applied to source and gate electrodes in some cases. In this embodiment, an electric field produced by application of a high voltage can be reduced by the field-plate electrode 13 provided.

Thereafter, steps such as the steps of electrically interconnecting the source electrode 5, the drain electrode 6, and the gate electrode 8 and forming pads for the source electrode 5, the drain electrode 6, and the gate electrode 8 are performed to complete an MIS type AlGaN/GaN HEMT according to this embodiment.

The AlGaN/GaN HEMT according to this embodiment has an MIS type structure in which the gate insulating film is disposed between the compound semiconductor and the gate electrode. Here, the gate insulating film 7 is disposed between the compound semiconductor multilayer structure 2 and the gate electrode 8 with the insertion metal layer 4 that vertically aligns with the gate electrode 8 between the gate insulating film 7 and the compound semiconductor multilayer structure 2. In a configuration in which the insertion metal layer 4 is not provided, unwanted charge can build up in the gate insulating film or at the interface between the compound semiconductor multilayer structure and the gate insulating film. In the configuration of this embodiment, in contrast, the insertion metal layer 4 prevents the buildup of unwanted charge, thereby improving the reliability of the device.

The AlGaN/GaN HEMT according to this exemplary variation has an MIS type structure in which an insulating film is disposed between the compound semiconductor and the field-plate electrode. Here, an insulating film (the gate insulating film 7) is disposed between the compound semiconductor multilayer structure 2 and the field-plate electrode 13 with the insertion metal layer 11 that aligns with the field-plate electrode 13 between them. In a configuration in which the insertion metal layer 11 is not provided, unwanted charge can build up in the insulating film or at the interface between the compound semiconductor multilayer structure and the insulating film. In the configuration of this exemplary variation, in contrast, the insertion metal layer 11 prevents the buildup of unwanted charge. Accordingly, such unwanted charge is not produced and electric fields produced by application of a high voltage to the drain electrode are reduced by the field-plate electrode 13, thereby significantly improving the reliability of the device.

Furthermore, in the AlGaN/GaN HEMT according to this exemplary variation, the p-type cap layer 2e of the compound semiconductor multilayer structure 2 is provided only in a region located under and vertically aligned with the gate electrode and, during non-operation, there is practically no 2DEG, except under the p-type cap layer 2e. This configuration provides a desired normally-off operation. That is, when the gate voltage is off, there is not 2DEG in the channel and therefore the normally-off state is provided; when the gate voltage is on, desired 2DEG is produced in the channel to drive.

Here, an experiment conducted to investigate characteristics of the AlGaN/GaN HEMT according to this exemplary variation will be described. For comparison with this embodiment, an AlGaN/GaN HEMT that does not include insertion metal layers will be taken as an example.

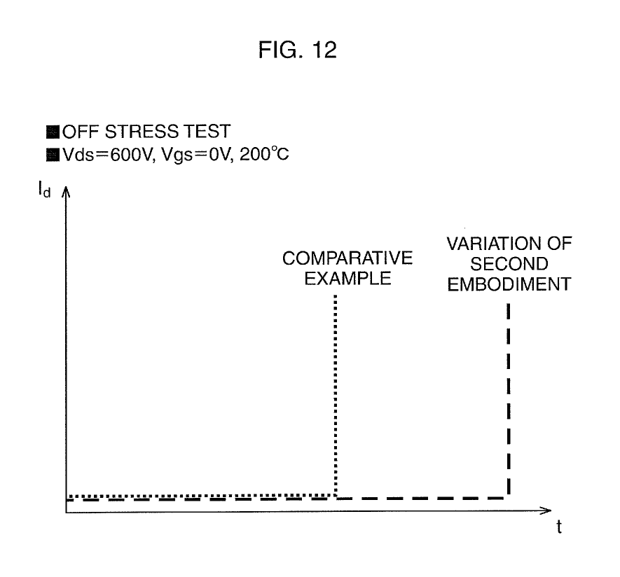

In this exemplary variation, a voltage Vds was continuously applied across the source and drain to determine the time that elapsed before breakdown (off stress test). Here, a Vds of 600 V was applied at a temperature of 200° C. and the gate-source voltage Vgs was set to 0 V. FIG. 12 gives the results of the experiment. The results demonstrate that the time required for breakdown to occur increases and the reliability of the device is improved in this embodiment as compared with the comparative example.

As has been described above, this exemplary variation implements a highly reliable, high-withstand-voltage AlGaN/GaN HEMT that has an MIS structure in which an insulating film is provided between a compound semiconductor multilayer structure 2 and a gate electrode 8 and yet minimizes a rise in on-state resistance and threshold variations.

### Third Embodiment

In a third embodiment, a Power Factor Correction (PFC) circuit including an AlGaN/GaN HEMT according to one selected from among the first and second embodiments and their variations will be disclosed.

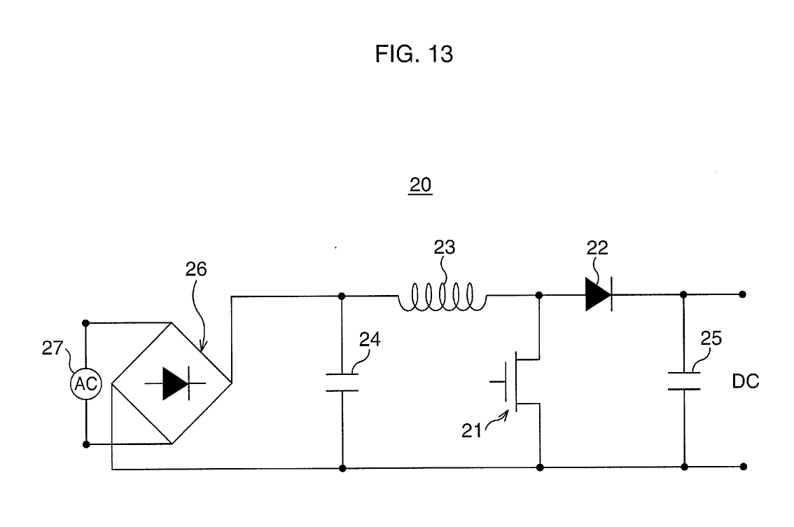

FIG. 13 is a connection diagram of the PFC circuit.

The PFC circuit 20 includes a switch element (transistor) 21, a diode 22, a choke coil 23, capacitors 24, 25, a diode bridge 26, an alternating-current power supply (AC) 27. An AlGan/GaN HEMT according to one selected from among the first and second embodiments and their variations is applied to the switch element 21.

In the PFC circuit 20, a drain electrode of the switch element 21, an anode terminal of the diode 22, and one terminal of the choke coil 23 are connected together. A source electrode of the switch element 21, one terminal of the capacitor 24, and one terminal of the capacitor 25 are connected together. The other terminal of the capacitor 24 and the other terminal of the choke coil 23 are connected together. The other terminal of the capacitor 25 and a cathode terminal of the diode 22 are connected together. The AC 27 is connected between both terminals of the capacitor 24 through a diode bridge 26. A direct-current power supply (DC) is connected between both terminals of the capacitor 25. A PFC controller, not depicted, is connected to the switch element 21.

In this embodiment, an AlGaN/GaN HEMT according to one selected from among the first and second embodiments and their variations is applied to the PFC circuit 20. This implements a highly reliable PFC circuit 30.

### Fourth Embodiment

In a fourth embodiment, a power supply device including an AlGaN/GaN HEMT according to one selected from among the first and second embodiments and their variations will be disclosed.

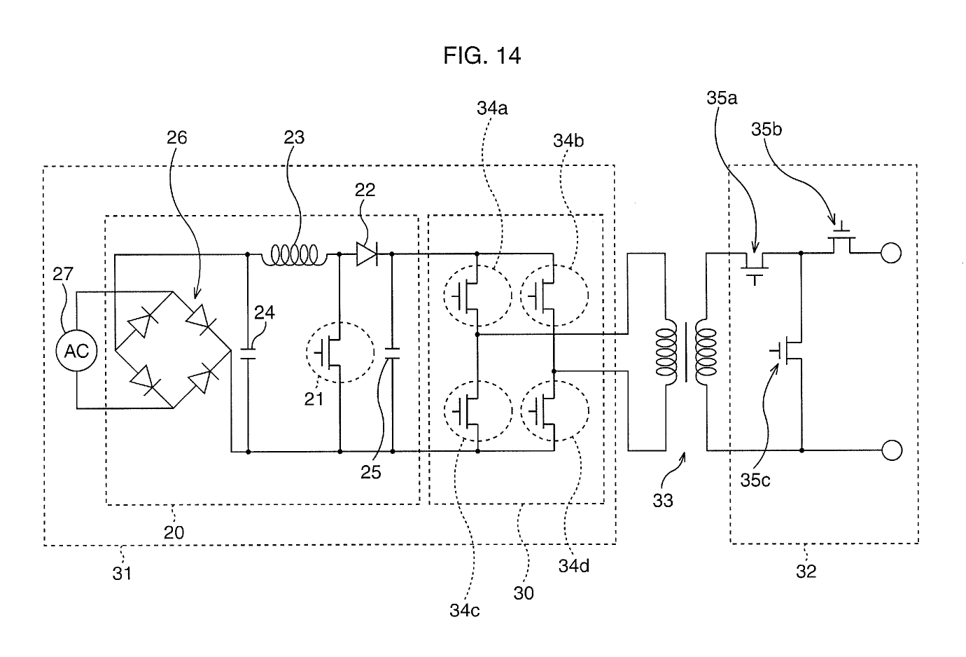

FIG. 14 is a connection diagram schematically illustrating a configuration of the power supply device according to the fourth embodiment.

The power supply device according to this embodiment includes a high-voltage primary circuit 31, a low-voltage secondary circuit 32, and a transformer 33 disposed between the primary circuit 31 and the secondary circuit 32.

The primary circuit 31 includes a PFC circuit 20 according to the third embodiment, an inverter circuit, for example a full-bridge inverter circuit 30, connected between both terminals of a capacitor 25 of the PFC circuit 20. The full-bridge inverter circuit 30 includes a plurality of (four in this example) switch elements 34a, 34b, 34c and 34d.

The secondary circuit 32 includes a plurality of (three in this example) switch elements 35a, 35b and 35c.

In this embodiment, the PFC circuit of the primary circuit 31 is a PFC circuit 20 according to the third embodiment and the switch elements 34a, 34b, 34c and 34d of the full-bridge inverter circuit 30 are AlGaN/GaN HEMTs according to one selected from among the first and second embodiments and their variations. On the other hand, the switch elements 35a, 35b and 35c of the secondary circuit 32 are conventional silicon-based MIS FETs.

In this embodiment, a PFC circuit 20 according to the third embodiment and AlGaN/GaN HEMTs according to one selected from among the first and second embodiments and their variations are applied to the primary circuit 31, which is a high-voltage circuit. This configuration implements a highly reliable high-power power supply device.

### Fifth Embodiment

In a fifth embodiment, a high-frequency amplifier including AlGaN/GaN HEMTs according to one selected from among the first and second embodiments and their variations will be disclosed.

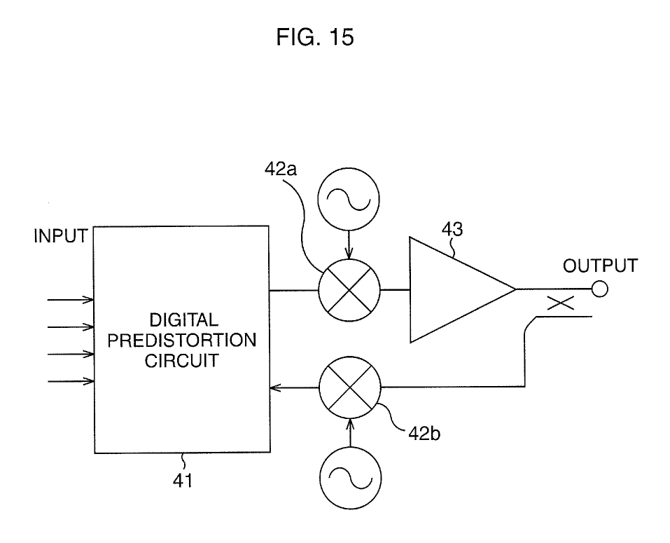

FIG. 15 is a connection diagram schematically illustrating a configuration of the high-frequency amplifier according to the fifth embodiment.

The high-frequency amplifier according to this embodiment includes a digital predistortion circuit 41, mixers 42a and 42b and a power amplifier 43.

The digital predistortion circuit 41 compensates for nonlinear distortion of an input signal. The mixer 42a mixes an input signal whose linear distortion has been compensated for with an AC signal. The power amplifier 43 amplifies an input signal mixed with an AC signal and includes an AlGaN/GaN HEMT according to one selected from among the first and second embodiments and their variations. It is noted that in FIG. 15, a switching operation of a switch, for example, enables an output signal to be mixed with the AC signal at the mixer 42b and sent back to the digital predistortion circuit 41.

In this embodiment, an AlGaN/GaN HEMT according to one selected from among the first and second embodiments and their variations is applied to a high-frequency amplifier. This implements a highly reliable high-frequency amplifier having a high withstand voltage.

### Alternative Embodiments

Compound semiconductor devices that are AlGaN/GaN HEMTs have been illustrated in the first and second embodiments and their variations. The compound semiconductor device can be applied to other HEMTs such as those described below as well, in addition to AlGaN/GaN HEMTs.

### Alternative Exemplary Device 1

In this exemplary embodiment, an InAlN/GaN HEMT is disclosed as a compound semiconductor device.

InAlN and GaN are compound semiconductors that have lattice constants that can be made closer to each other by adjusting the composition ratios. In this case, the electron transit layer in the first and second embodiments described above is made of i-GaN, the intermediate layer is made of AlN, the electron donor layer is made of n-InAlN, and the p-type cap layer is made of p-GaN. Also in this case, piezoelectric polarization practically does not occur and therefore two-dimensional electron gas is produced primarily by spontaneous polarization of InAlN.

This exemplary embodiment implements a highly reliable, high-withstand-voltage InAlN/GaN HEMT that has an MIS structure in which an insulating film is provided between a compound semiconductor and a gate electrode and yet minimizes a rise in on-state resistance and threshold variations, like the AlGaN/GaN HEMTs described above.

### Alternative Exemplary Device 2

In this exemplary embodiment, an InAlGaN/GaN HEMT is disclosed as a compound semiconductor device.

GaN and InAlGaN are compound semiconductors and the lattice constant of the latter can be made smaller than that of the former by adjusting the composition ratio. In this case, the electron transit layer in the first and second embodiments described above is made of i-GaN, the intermediate layer is made of i-InAlGaN, the electron donor layer is made of n-InAlGaN, and the p-type cap layer is made of p-GaN.

This exemplary embodiment implements a highly reliable, high-withstand-voltage InAlGaN/GaN HEMT that has an MIS structure in which an insulating film is provided between a compound semiconductor and a gate electrode and yet minimizes a rise in on-state resistance and threshold variations, like the AlGaN/GaN HEMTs described above.

According to the modes described above, a highly reliable semiconductor device is implemented that has an MIS structure in which an insulating film is provided between a semiconductor layer and an electrode and yet minimizes a rise in on-state resistance and threshold variations.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a semiconductor layer;
a first conductive layer in contact with a surface of the semiconductor layer;
an insulating film formed on the first conductive layer; and
a second conductive layer formed above the first conductive layer with the insulating film between the first conductive layer and the second conductive layer.

2. The semiconductor device according to claim 1, wherein the semiconductor layer comprises a semiconductor cap layer as the top layer of the semiconductor layer, the semiconductor cap layer being opposite in polarity to the rest of the semiconductor layer.

3. The semiconductor device according to claim 2, wherein the first conductive layer is formed on the semiconductor cap layer.

4. The semiconductor device according to claim 3, wherein the first conductive layer comprises as a material Ti, Ni, or Pd or any combination thereof.

5. The semiconductor device according to claim 3, wherein the second conductive layer is a gate electrode.

6. The semiconductor device according to claim 1, wherein the first conductive layer comprises as a material Ta or Al or any combination thereof.

7. The semiconductor device according to claim 6, wherein the second conductive layer is a field-plate electrode.

8. The semiconductor device according to claim 7, further comprising a source electrode and a drain electrode,
wherein the second conductive layer is electrically connected to the drain electrode.

9. A method for fabricating a semiconductor device, the method comprising:
forming a semiconductor layer;
forming a first conductive layer in contact with a surface of the semiconductor layer;
forming an insulating film on the first conductive layer; and
forming a second conductive layer in a region on the insulating film, the region being located above and vertically aligned with the first conducive layer.

10. The method for fabricating a semiconductor device according to claim 9, wherein the semiconductor layer comprises a semiconductor cap layer as the top layer of the semiconductor layer, the semiconductor cap layer being opposite in polarity to the rest of the semiconductor layer.

11. The method for fabricating a semiconductor device according to claim 10, wherein in the forming the first conductive layer, the semiconductor cap layer is shaped into the same geometry as the first conductive layer.

12. The method for fabricating a semiconductor device according to claim 11, wherein the first conductive layer comprises as a material Ti, Ni, or Pd or any combination thereof.

13. The method for fabricating a semiconductor device according to claim 11, wherein the second conductive layer is a gate electrode.

14. The method for fabricating a semiconductor device according to claim 9, wherein the first conductive layer comprises as a material Ta or Al or any combination thereof.

15. The method for fabricating a semiconductor device according to claim 14, wherein the second conductive layer is a field-plate electrode.

16. The method for fabricating a semiconductor device according to claim 15, wherein in the forming the first conductive layer, the second conductive layer is formed monolithically with a drain electrode.

17. A power supply device comprising a transformer, and a high-voltage circuit and a low-voltage circuit disposed with the transformer between the high-voltage and the low-voltage circuits,
wherein the high-voltage circuit comprises a transistor, the transistor comprising:
a semiconductor layer;
a first conductive layer in contact with a surface of the semiconductor layer;
an insulating film formed on the first conductive layer; and
a second conductive layer formed above the first conductive layer with the insulating film between the first conductive layer and the second conductive layer.
